(19) United States
(12) Patent Application Publication
(10) Pub. No.: US 2025/0285923 A1
(43) Pub. Date: Sep. 11, 2025

(54) SEMICONDUCTOR DEVICE INCLUDING A TEST LINE PORTION AND METHOD OF MAKING AND TESTING THE SAME

(71) Applicant: Taiwan Semiconductor Manufacturing Company Limited, Hsinchu (TW)

(72) Inventors: Chen-Hsuan Yen, Taichung City (TW); Jen-Yuan Chang, Hsinchu City (TW)

(21) Appl. No.: 18/600,838

(22) Filed: Mar. 11, 2024

(51) Int. Cl. H01L 21/66; H01L 23/00; H01L 23/28; H01L 23/48; H01L 23/58; H01L 25/10

(52) U.S. Cl. CPC H01L 22/34; H01L 23/28; H01L 23/481; H01L 23/585; H01L 24/08; H01L 24/80; H01L 25/105; H01L 2224/08145; H01L 2224/80895; H01L 2224/80896

(57) ABSTRACT

A semiconductor device includes a first die including a first die edge and a first die seal ring, a second die bonded to the first die and including a second die edge and a second die seal ring, and a test line portion including at least one of a first die test line portion in the first die between the first die edge and the first die seal ring, or a second die test line portion in the second die between the second die edge and the second die seal ring.

### BACKGROUND

A die (e.g., semiconductor die) may include a seal ring also known as a scribe line seal or kerf seal. The seal ring may serve multiple purposes and functions. The seal ring may serve as a boundary around the die, enclosing active circuitry and other components as well as protecting the circuitry from external contaminants, moisture, and mechanical damage. The seal ring may also provide electrical and thermal isolation between the active circuitry on the die and components outside the seal ring. The seal ring may also add structural strength to the die and thereby inhibit warping or cracking of the die.

The seal ring may also include alignment marks or fiducials that aid in the precise positioning of the die during assembly and packaging and thereby improve the overall quality and reliability of the device including the die. The seal ring may also provide scribe lines for guiding a dicing tool to make precise cuts in separating the die from a wafer.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1A is a vertical cross-sectional view of a semiconductor device according to one or more embodiments.

FIG. 1B is a schematic illustration of the semiconductor device in a top-down (z-direction) view according to one or more embodiments.

FIG. 1C is an exploded perspective view of the semiconductor device according to one or more embodiments.

FIG. 2A is an intermediate structure including the first bonding film on the carrier substrate according to one or more embodiments.

FIG. 2B is an intermediate structure including the first die and third die on the first bonding film according to one or more embodiments.

FIG. 2C is an intermediate structure including the first encapsulation layer on the first bonding film according to one or more embodiments.

FIG. 2D is an intermediate structure including the second layer on a second carrier substrate according to one or more embodiments.

FIG. 2E is an intermediate structure including the second layer on the first layer according to one or more embodiments.

FIG. 2F is an intermediate structure after removal of the second carrier substrate according to one or more embodiments.

FIG. 2G is an intermediate structure including a multilayer opening in the passivation layer and the second bonding film according to one or more embodiments.

FIG. 2H is an embodiment structure including the metal bump on the die bonding pad in the multilayer opening according to one or more embodiments.

FIG. 3 is a flow chart illustrating a method of forming a semiconductor device according to one or more embodiments.

FIG. 4 is a schematic illustration of a method of testing the semiconductor device according to one or more embodiments.

FIG. 5A is a vertical cross-sectional view of the semiconductor device having a first alternative design according to one or more embodiments.

FIG. 5B is a schematic illustration of a method of testing the semiconductor device having the first alternative design according to one or more embodiments.

FIG. 6 is a flow chart illustrating a method of testing the semiconductor device according to one or more embodiments.

FIG. 7 is a vertical cross-sectional view of the semiconductor device having a second alternative design according to one or more embodiments.

FIG. 8 is a vertical cross-sectional view of the semiconductor device having a third alternative design according to one or more embodiments.

### DETAILED DESCRIPTION

The following disclosure provides many different embodiments, or examples, for implementing different features of the invention. Specific embodiments or examples of components and arrangements are described below to simplify the present disclosure. These are, of course, merely examples and are not intended to be limiting. For example, dimensions of elements are not limited to the disclosed range or values, but may depend upon process conditions and/or desired properties of the device. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact. Various features may be arbitrarily drawn in different scales for simplicity and clarity.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The tool may be otherwise oriented (rotated 90 degrees or at other orientations) and the spatially relative descriptors used herein may likewise be interpreted accordingly.

A related die (e.g., semiconductor die, a stack of integrated semiconductor chips, chiplet, etc.) such as a central processing unit (CPU) die or a static random access memory (SRAM) die may include a seal ring design. In such related dies, there may be no metal pattern or devices located outside the seal ring (i.e., between the die edge and the seal ring). In these related dies, an amount of the die outside the seal ring may be substantially uniform around the outer periphery of the die. That is, a variation in the distance between the die edge and the seal ring may be within about 10% (i.e., no greater than about 10%).

At least one embodiment of the present disclosure may include a novel semiconductor device including a test line portion (e.g., die overhang test line portion). At least one embodiment may include the test line portion in at least one die (e.g., semiconductor die) of a die module including a plurality of stacked dies (e.g., chiplet stack) to provide design flexibility. The test line portion may be located between a seal ring in the die and an edge of the die (e.g., the die edge).

The test line portion may include a test line electrical connection design that may allow for tool testing. In at least one embodiment, the test line portion may be configured to permit testing of the semiconductor device such as by a wafer acceptance testing (WAT) device. In at least one embodiment, the test line portion may be used to monitor an influence of process (e.g., manufacturing process) on the semiconductor device (e.g., an influence on an integrated circuit in the semiconductor device). In at least one embodiment, the test line portion may be used to monitor a charging damage effect on the semiconductor device. The test line portion may be observable from a cross section of the semiconductor device.

In at least one embodiment, the test line portion may be included in a die overhang (e.g., a portion of the die outside the die seal ring) and referred to as a die overhang test line portion. The die overhang test line portion may include the same substrate (e.g., semiconductor substrate; silicon substate) as the rest of the die. In the die overhang test line portion, a distance between the seal ring and the die edge may be greater than in other parts of the die. The die overhang test line portion may include a metal layer pattern. In at least one embodiment, the die overhang test line portion may include test line outside the die seal ring surrounding a functional circuit portion of the die. The die overhang test line portion may serve as a process monitor. The die overhang test line portion may or may not include its own seal ring (i.e., a seal ring outside of the die seal ring).

The test line portion may provide an innovative design. A test site for the test line portion may be provided by performing a photolithographic process. In the photolithographic process, a passivation layer may be etched by an etching process (e.g., a Pass2_etch) through openings in a patterned photoresist mask to expose the test site. In at least one embodiment, the etching process may expose a metal pad (e.g., open an aluminum pad) that may be used for tool testing such as WAT tool testing.

In at least one embodiment, the semiconductor device may include a first die and a second die bonded to the first die. The semiconductor device may also include a substrate and the first die may be located in a first level on the substrate. The second die may be located in a second level adjacent the first level and have a width greater than a width of the first die. A third die may also be located adjacent the first die in the first level. The third die may include a dummy die (e.g., non-functioning die).

In at least one embodiment, the second die may include the second die test line portion. The second die may also be electrically coupled to the first die by an electrical connection (e.g., by a through silicon via (TSV)). The second die test line portion in the second die may, therefore, be used as a test line. In particular, the second die test line portion in the second die may, therefore, be used to monitor the influence of the process (e.g., manufacturing process) on the semiconductor device (e.g., the first die and the second die) and the integrated circuit in the semiconductor device. In particular, a test site may be formed in the second die by an etching process (e.g., a Pass2_etch). The test site may include, for example, a metal pad (e.g., aluminum pad) expose during the etching process. In particular, the metal pad may be contacted by one or more probes of a testing tool (e.g., a WAT testing tool).

In at least one embodiment, the first die may include the first die test line portion. The first die may also be electrically coupled to the second die by an electrical connection (e.g., by a TSV). The first die test line portion in the first die may, therefore, be used as a test line. In particular, the first die test line portion in the first die may be used to monitor the influence of the process on the semiconductor device (e.g., the first die and the second die) and the integrated circuit in the semiconductor device. The test site may again be formed in the second die as described above and electrically coupled to the first die test line portion in the first die.

In at least one embodiment, the first die may include a first die test line portion. However, the first die test line portion may not be electrically coupled to the first die and/or the second die. In this case, the first die test line portion may not be used for testing, but may be used, for example, as a heat dissipation structure. The first die test line portion may also be used to reduce the area of the third die. In at least one embodiment, the first die test line portion may completely eliminate the need for the third die. This may help to reduce cost and balance stress (e.g., stress caused by mismatched coefficient of thermal expansions (CTEs)) in the level of the first die (e.g., same level, same structure).

In at least one embodiment, the first die may include a first die test line portion and the second die may include a second die test line portion. This may allow for separate monitoring of the first die and the second die. In particular, this may allow the first die and the second die to be easily analyzed by separate WAT testing. Separate monitoring may be especially advantageous where the first die and the second die are formed in different processes. Electrical die sorting (EDS) may affect the affordability of the die module.

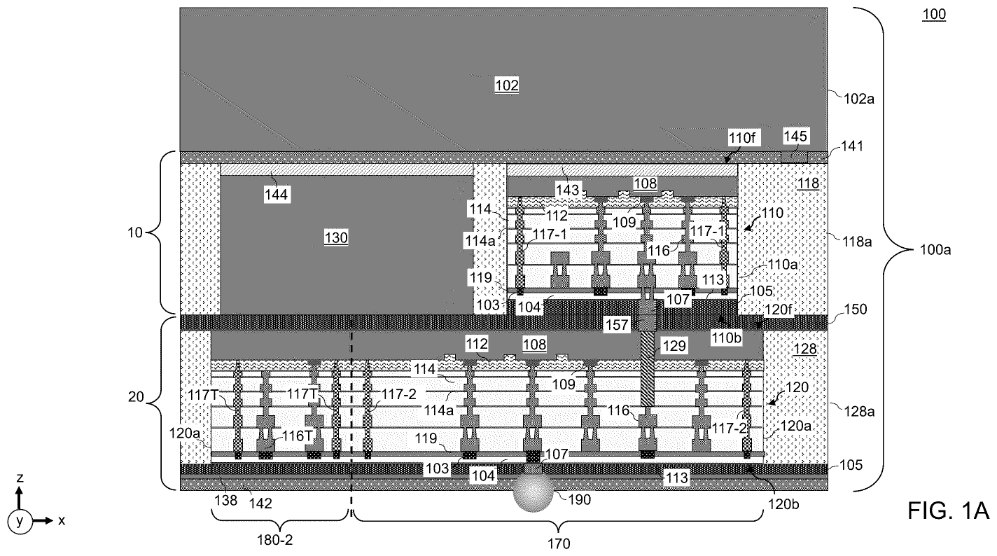

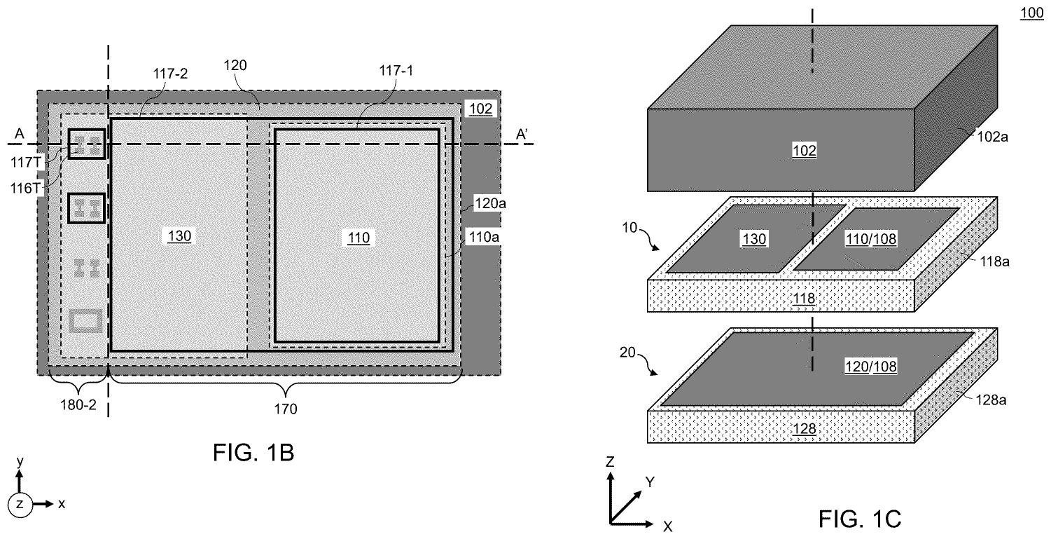

Referring to the drawings, FIG. 1A is a vertical cross-sectional view of a semiconductor device 100 according to one or more embodiments. The semiconductor device 100 may include a die stack (e.g., a chiplet stack) including a plurality of dies (e.g., semiconductor dies). As illustrated in FIG. 1A, the semiconductor device 100 may include a first layer 10 including a first encapsulation layer 118 and a first die 110 in the first encapsulation layer 118. The semiconductor device 100 may also include a second layer 20 including a second encapsulation layer 128 and a second die 120 in the second encapsulation layer 128. The second die 120 may be electrically coupled to the first die 110. The first die 110 and second die 120 may together form an integrated circuit in the semiconductor device 100.

As further illustrated in FIG. 1A, the first die 110 and second die 120 may be arranged in the semiconductor device 100 with a front-to-back arrangement. In particular, a front side 120f of the second die 120 may be bonded to a backside 110b of the first die 110. A backside 120b of the second die 120 may face away from the first die 110 and a frontside 110f of the first die 110 may face away from the second die 120.

In at least one embodiment, the first die 110 and/or the second die 120 may include a second die test line portion 180-2. The second die test line portion 180-2 may provide for the testing of the semiconductor device 100 (e.g., allow monitoring an effect of processing on the semiconductor device 100).

As further illustrated in FIG. 1A, the first die 110 may include a die substrate 108. The die substrate 108 may include a semiconductor material such as silicon, germanium, silicon germanium, etc. In at least one embodiment, the first die 110 may be built upon a silicon wafer in wafer level processing. The first die 110 may be formed by dicing the silicon wafer into a plurality of dies including the first die 110. The first die 110 may, therefore, include a portion of silicon wafer as the die substrate 108. The dicing of the silicon wafer may also form a first die edge 110a of the first die 110. The first die edge 110a may be formed around an entire periphery of the first die 110. One or more active devices may be formed in and/or on the die substrate 108. The active devices may include one or more gate electrodes 109 formed on the die substrate 108. The gate electrodes 109 may be formed of a conductive material such as metal, polysilicon, etc.

The first die 110 may also include one or more interlayer dielectric (ILD) layers 112 on the die substrate 108. The gate electrodes 109 may be located on the die substrate 108 in the ILD layers 112. The ILD layers 112 may include, for example, undoped silicon glass (USG), fluorosilicate glass (FSG), silicon oxide (SiₓO_{y}), hafnium silicate (HfSiO₄), zirconium silicate (ZrSiO₄), tetraethyl orthosilicate (TEOS), hydrogen silsesquoxane (HSQ), etc. Other suitable dielectric materials may be used for the ILD layers 112. The ILD layers 112 may be formed by a suitable deposition method such as chemical vapor deposition (CVD), plasma-enhanced CVD (PECVD), low pressure chemical vapor deposition (LPCVD), physical vapor deposition (PVD), atomic layer deposition (ALD), spin-on coating, or lamination.

One or more intermetal dielectric (IMD) layers 114 may be formed on the ILD layers 112. The IMD layers 114 may also include, for example, undoped silicon glass (USG), fluorosilicate glass (FSG), silicon oxide, hafnium silicate (HfSiO₄), zirconium silicate (ZrSiO₄), tetraethyl orthosilicate (TEOS), hydrogen silsesquoxane (HSQ), etc. Other suitable dielectric materials may be used for the IMD layers 114. The IMD layers 114 may be separated by one or more etch stop layers 114a. The etch stop layers 114a may include, for example, silicon nitride (SixNy), silicon carbide, etc. Other suitable materials may be used for the etch stop layers 114a. The IMD layers 114 and etch stop layers 114a may be formed by a suitable deposition method such as CVD, PVD, PECVD, LPCVD, ALD, spin-on coating, lamination, etc.

The first die 110 may also include one or more metal features 116 in the IMD layers 114. The metal features 116 may be electrically connected to the gate electrodes 109. The metal features 116 may include, for example, metal vias and metal traces (e.g., metal lines). The metal vias may be formed between the metal traces and interconnect the metal traces in the various IMD layers 114. The metal features 116 may be formed of suitable metals such as copper, copper alloys, aluminum, aluminum alloys, or some combination thereof. Other suitable conductive metal materials for use as the metal features 116 are within the contemplated scope of disclosure.

Referring to FIGS. 1A and 1B, the first die 110 may also include a first die seal ring 117-1 extending through the IMD layers 114 and into the ILD layers 112. The first die seal ring 117-1 may contact the substrate 108. The first die seal ring 117-1 may be electrically isolated from the metal features 116 and formed so as to surround (e.g., encircle) a functional circuit portion 170 of the first die 110. The first die seal ring 117-1 may provide protection for the features of the first die 110 from water, chemicals, residue, and/or contaminants that may be present during the processing of the first die 110. The first die seal ring 117-1 may be formed of a conductive material (e.g., metal material) and more particularly, may be formed of the same material, at the same time, and by the same process as the metal features 116. More particularly, the first die seal ring 117-1 may include conductive lines and via structures that are connected to each other, and may be formed simultaneously with the metal lines and conductive vias of the metal features 116. For example, the first die seal ring 117-1 may include copper at an atomic percentage greater than 80%, such as greater than 90% and/or greater than 95% although greater or lesser percentages may be used.

In at least one embodiment, the metal features 116 and/or the first die seal ring 117-1 may be formed by a dual-Damascene process or by multiple single Damascene processes. A single-Damascene process may generally form and fill a single feature with copper per Damascene stage. A dual-Damascene process may generally form and fill two features with a metal (e.g., copper) at once in a single step. For example, a trench and overlapping through-hole may both be filled with a single metal deposition using a dual-Damascene process. In alternative embodiments, the metal features 116 and/or the first die seal ring 117-1 may be formed by an electroplating process.

In at least one embodiment, the metal features 116 and/or the first die seal ring 117-1 may be formed by a Damascene process in which the IMD layers 114 are patterned (e.g., by a photolithographic process) to form openings such as trenches and/or though-holes (e.g., via holes). A metal layer (e.g., copper layer) may then be deposited by a suitable deposition method such as CVD, PVD, PECVD, LPCVD, ALD, spin-on coating, lamination, etc. A planarization process, such as chemical-mechanical planarization (CMP) may then be performed to remove excess metal (e.g., overburden).

The patterning, metal deposition, and planarizing processes may be performed separately for each dielectric layer of the IMD layers 114 in order to form an interconnect structure made up of the metal features 116. For example, a dielectric layer of the IMD layers 114 may be deposited on the ILD layers 112 by a suitable deposition method such as CVD, PVD, PECVD, LPCVD, ALD, spin-on coating, lamination, etc. One or more openings may then be formed in the dielectric layer. The openings may be formed, for example, using a photolithographic process. In that process, a photoresist mask (not shown) may be formed on an upper surface of the ILD layers 112. The photoresist mask may be photolithographically patterned to include one or more openings. An etching process (e.g., wet etching, dry etching, etc.) may then be used to form one or more openings in the dielectric layer through the openings in the photoresist mask. The photoresist mask may be subsequently removed by ashing, dissolving the photoresist mask or by consuming the photoresist mask during the etch process.

A suitable deposition method (e.g., CVD, PVD, PECVD, LPCVD, ALD, spin-on coating, lamination, etc.) may then be performed to fill the openings in the dielectric layer of the IMD layers 114. A planarization process may then be performed to remove the overburden and form the metal features 116 in the dielectric layer. These process steps may be repeated to form the IMD layers 114 and the corresponding metal features 116 and first die seal ring 117-1 and thereby complete the interconnect structure and first die seal ring 117-1.

A passivation layer 119 may be formed on the IMD layers 114. In at least one embodiment, the passivation layer 119 may include silicon oxide, silicon nitride, benzocyclobutene (BCB) polymer, polyimide (PI), polybenzoxazole (PBO) or a combination thereof. Other suitable dielectric materials are within the contemplated scope of disclosure. The passivation layer 119 may be formed by a suitable suitable deposition method such as CVD, PVD, PECVD, LPCVD, ALD, spin-on coating, lamination, etc.

One or more contact pads 103 may be formed through an opening in the passivation layer 119 onto the metal features 116 and the first die seal ring 117-1. The contact pads 103 may include a metal such as aluminum, copper, etc. The contact pads 103 may be formed by performing a photolithographic process (similar to the photolithograpic process described above for forming the metal features 116 in the first die 110) to form the opening, and depositing a metal layer in the opening by a suitable deposition process such as CVD, PVD, PECVD, LPCVD, ALD, spin-on coating, lamination, etc.

A gap fill dielectric layer 104 may then be formed on the passivation layer 119 and over and around the contact pads 103. The gap fill dielectric layer 104 may be formed of the same material as the IMD layers 114 (e.g., undoped silicon glass (USG), fluorosilicate glass (FSG), silicon oxide, hafnium silicate (HfSiO₄), zirconium silicate (ZrSiO₄), tetraethyl orthosilicate (TEOS), hydrogen silsesquoxane (HSQ), etc. The gap fill dielectric layer 104 may be formed by a suitable deposition process such as CVD, PVD, PECVD, LPCVD, ALD, spin-on coating, lamination, etc.

A backside etch stop layer 113 may be formed on the gap fill dielectric layer 104. The backside etch stop layer 113 may include, for example, silicon nitride (SixNy), silicon carbide, etc. Other suitable materials may be used for the backside etch stop layer 113. The backside etch stop layer 113 may be formed by a suitable deposition method such as CVD, PVD, PECVD, LPCVD, ALD, spin-on coating, lamination, etc.

A die bonding film 105 (e.g., hybrid bonding film) may be formed on the backside etch stop layer 113. The die bonding film 105 may include an oxide such as silicon oxide. The die bonding film 105 may be formed by a suitable deposition process such as CVD, PVD, etc. One or more die bonding pads 107 may then be formed through a multilayer opening including an opening in the die bonding film 105, an opening in the backside etch stop layer 113, an opening in the gap fill dielectric layer 104 and an opening in the passivation layer 119, and contact a metal feature 116 in the IMD layers 114. The die bonding pads 107 may be formed of a material similar to the material of the metal features 116. The die bonding pads 107 may be formed by performing a photolithographic process (similar to the photolithograpic process described above for forming the metal features 116 in the first die 110) to form the multilayer opening including the openings in the die bonding film 105, backside etch stop layer 113, gap fill dielectric layer 104 and passivation layer 119, and depositing a metal layer in the multilayer opening by a suitable deposition process such as CVD, PVD, PECVD, LPCVD, ALD, spin-on coating, lamination, etc.

The first layer 10 of the semiconductor device 100 may also include a third die 130 in the first encapsulation layer 118. The third die 130 may include, for example, a dummy die (e.g., non-functional die). The third die 130 may have a thickness in the z-direction that is substantially the same as a thickness of the first die 110. The third die 130 may include, for example, a silicon die. Other suitable dielectric materials are within the contemplated scope of disclosure.

The first encapsulation layer 118 may be formed on the first die 110 and third die 130 so as to encapsulate at least a portion of the first die 110 and at least a portion of the third die 130. The first encapsulation layer 118 may include an organic material such as molding compound material (e.g., formed through molding), or an inorganic material (e.g., formed through PVD). The first encapsulation layer 118 may include, for example, silicon dioxide. The first encapsulation layer 118 may alternatively include undoped silicon glass (USG), fluorosilicate glass (FSG), SiC, SiON, SiN, SiCN, a low-K film, an extreme low-K (ELK) film, phosphor-silicate glass (PSG) and tetra-ethoxy-silane (TEOS). Other dielectric materials for use as the first encapsulation layer 118 are within the contemplated scope of disclosure. The first encapsulation layer 118 may alternatively or additionally include one or more molding compounds such as an epoxy molding compound (EMC).

As further illustrated in FIG. 1A, the first layer of the semiconductor device 100 may include a first bonding film 141 (e.g., fusion bonding film). The semiconductor device 100 may also include a first carrier substrate 102. The first carrier substrate 102 may be bonded to the first layer 10 (e.g., the first die 110, third die 130 and first encapsulation layer 118) by the first bonding film 141. A function of the first bonding film 141 may include bonding to the first die 110 and third die 130 and bonding the first die 110 and third die 130 to the first carrier substrate 102. The first bonding film 141 may include, for example, silicon oxynitride, silicon oxide, etc. Other suitable dielectric materials for the first bonding film 141 are within the contemplated scope of disclosure.

The first layer 10 of the semiconductor device 100 may also include a first die bonding layer 143. The first die 110 may be bonded to the first bonding film 141 by the first die bonding layer 143. The first die bonding layer 143 may have a width substantially the same as a width of the first die 110. The first die bonding layer 143 may have a thickness substantially the same as a thickness of the first bonding film 141.

The first layer 10 of the semiconductor device 100 may also include a third die bonding layer 144. The third die 130 may be bonded to the first bonding film 141 by the third die bonding layer 144. The third die bonding layer 144 may have a width substantially the same as a width of the third die 130. The third die bonding layer 144 may have a thickness substantially the same as a thickness of the first bonding film 141.

Each of the first die bonding layer 143 and the third die bonding layer 144 may include, for example, silicon oxynitride, silicon oxide, etc. Other suitable dielectric materials for the first die bonding layer 143 and the third die bonding layer 144 are within the contemplated scope of disclosure.

An alignment mark 145 may be located in the first bonding film 141. The alignment mark 145 may be located over a portion of the first encapsulation layer 118. The alignment mark 145 may have a width less than a width of the portion of the first encapsulation layer 118. The alignment mark 145 may have a thickness substantially the same as a thickness of the first bonding film 141. In at least one embodiment, the alignment mark 145 may include a die-to-wafer alignment mark. The alignment mark 145 may include a metal such as copper. Other suitable materials may be used in the alignment mark 145.

The second die 120 may have a structure that is substantially similar to the structure of the first die 110. The second die 120 may also be formed by a method that is substantially similar to the method of forming the first die 110. Similar to the first die 110, the second die 120 may be built upon a silicon wafer in wafer level processing. The second die 120 may be formed by dicing the silicon wafer into a plurality of dies including the second die 120. The second die 120 may, therefore, include a portion of silicon wafer as the die substrate 108. The dicing of the silicon wafer may also form a second die edge 120a of the second die 120. The second die edge 120a may be formed around an entire periphery of the second die 120.

The second die 120 may further include one or more active devices in and/or on the die substrate 108 including one or more gate electrodes 109. The second die 120 may also include one or more interlayer dielectric (ILD) layers 112 on the die substrate 108 and one or more intermetal dielectric (IMD) layers 114 on the ILD layers 112. The IMD layers 114 may be separated by one or more etch stop layers 114a.

The second die 120 may also include one or more metal features 116 and a second die seal ring 117-2 in the IMD layers 114. The second die seal ring 117-2 may have a structure and function substantially similar to a structure and function of the first die seal ring 117-1 in the first die 110. The second die seal ring 117-2 may be electrically isolated from the metal features 116 and formed so as to surround (e.g., encircle) a functional circuit portion 170 of the second die 120.

The second die 120 may additionally include one or more through silicon vias (TSV) 129 (e.g., second die vias) contacting one or more of the metal features 116. The TSVs 129 may extend through at least a portion of the IMD layers 114, the ILD layers 112 and the die substrate 108. A surface of the TSVs 129 may be substantially coplanar with a surface of the die substrate 108 in the second die 120. The TSVs 129 may include, for example, copper, gold, silver, aluminum or the like, or an alloy of these metals such as aluminum copper (AlCu) alloy. Other suitable materials for use in the TSVs 129 are within the contemplated scope of disclosure.

The second die 120 may also include the passivation layer 119 on the IMD layers 114, and one or more contact pads 103 may be formed through an opening in the passivation layer 119 onto the metal features 116 and the second die seal ring 117-2. The second die 120 may also include the gap fill dielectric layer 104 on the passivation layer 119 and over and around the contact pads 103. The second die 120 may also include the backside etch stop layer 113 on the gap fill dielectric layer 104.

The second encapsulation layer 128 may be formed on the second die 120 so as to encapsulate at least a portion of the second die 120. The second encapsulation layer 128 may include an organic material such as molding compound material (e.g., formed through molding), or an inorganic material (e.g., formed through PVD). The second encapsulation layer 128 may include, for example, silicon dioxide. The second encapsulation layer 128 may alternatively include undoped silicon glass (USG), fluorosilicate glass (FSG), SiC, SiON, SiN, SiCN, a low-K film, an extreme low-K (ELK) film, phosphor-silicate glass (PSG) and tetra-ethoxy-silane (TEOS). Other dielectric materials for use as the second encapsulation layer 128 are within the contemplated scope of disclosure. The second encapsulation layer 128 may alternatively or additionally include one or more molding compounds such as an epoxy molding compound (EMC).

The second layer 20 of the semiconductor device 100 may also include a die bonding film 105 and one or more die bonding pads 107 in the die bonding film 105. The die bonding pads 107 may contact one of the metal contact pads 103 on a metal feature 116. The second die 120 and second encapsulation layer 128 may be located on the die bonding film 105. The second layer 20 may further include a passivation layer 138. The die bonding film 105 may be located on the passivation layer 138. The passivation layer 138 may include, for example, silicon nitride, undoped silicate glass (USG) or silicon dioxide. Other materials for the passivation layer 138 are within the contemplated scope of disclosure. The second layer 20 may further include a second bonding film 142 (e.g., fusion bonding film). The passivation layer 138 may be located on the second bonding film 142. A function of the second bonding film 142 may include bonding elements of the second layer 20 (e.g., the second die 120) to the second carrier substrate 202. The second bonding film 142 may be formed of the same materials as the first bonding film 141 and may be formed using the same process as the first bonding film 141. The second bonding film 142 may include, for example, silicon oxynitride or silicon dioxide. Other suitable dielectric materials for the second bonding film 142 are within the contemplated scope of disclosure. One or more metal bumps 190 may be formed in the passivation layer 138 and second bonding film 142 so as to contact the die bonding pads 107 (in the die bonding film 105) that are connected to the metal features 116 of the second die 120. The metal bumps 190 may be used to electrically couple the semiconductor device 100 to a separate substrate.

The second layer 20 of the semiconductor device 100 may also include a bonding layer 150. The bonding layer 150 may include a hybrid bonding film and serve as a hybrid bond interface. The second layer 20 of the semiconductor device 100 may be bonded to the first layer 10 of the semiconductor device 100 by the bonding layer 150. The bonding layer 150 may extend the entire width of the semiconductor device 100 in the x-direction. The bonding layer 150 may also include, for example, silicon oxynitride, silicon oxide, etc. Other suitable dielectric materials for the bonding layer 150 are within the contemplated scope of disclosure. The bonding layer 150 may include a bonding layer bonding pad 157 connected to the TSV 129 in the second die 120 and to the die bonding pad 107 in the first die 110. The bonding layer bonding pad 157 may be formed of the same materials as the die bonding pad 107. Other suitable materials are within the contemplated scope of disclosure. In at least one embodiment, a bond between the first layer 10 and the second layer 20 may include a hybrid bond (e.g., oxide bond, metal bond) including the bonding layer 150 and the bonding layer bonding pad 157.

A redistribution layer structure (not shown) may optionally be formed in the bonding layer 150. The optional redistribution layer structure may be used to interconnect the dies in the first layer 10 (e.g., connect the first die 110 to other dies in the first layer 10). The optional redistribution layer structure may also be used to connect the dies in the first layer 10 (e.g., first die 110) to the dies in the second layer 20 (e.g., second die 120).

As illustrated in FIG. 1A, the semiconductor device 100 may include a sidewall 100a that extends along an entire height of the semiconductor device 100 from the second bonding film 142 to the first carrier substrate 102. The sidewall 100a may include primarily a sidewall 128a of the second encapsulation layer 128, a sidewall 118a of the first encapsulation layer 118a and a sidewall 102a of the first carrier substrate 102. The sidewall 100a may also include an end of the second bonding film 142, an end of the passivation layer 138, an end of the bonding layer 150, and an end of the first bonding film 141.

The second die test line portion 180-2 may be integrally formed as one continuous unit with the remainder of the second die 120. The second die test line portion 180-2 may be located adjacent the functional circuit portion 170 of the second die 120. The second die test line portion 180-2 may be bounded on one lateral side (e.g., in the x-y plane) by the functional circuit portion 170 and bounded on the three remaining lateral sides by the second die edge 120a. In at least one embodiment, the second die test line portion 180-2 may be located in a region of the second die 120 where a distance between the second die seal ring 117-2 and the die edge 120a may be greater than in other parts of the second die 120.

The dashed line in FIG. 1A may be considered an imaginary boundary between the functional circuit portion 170 and the second die test line portion 180-2. The second die 120 may not be separated at the boundary but may be continuously formed across the boundary. The substrate 108 included in the functional circuit portion 170 may extend into and form part of the second die test line portion 180-2, the ILD layers 112 included in the functional circuit portion 170 may extend into and form part of the second die test line portion 180-2, and so on.

The second die test line portion 180-2 may include one or more test line portion metal features 116T that are substantially similar to the metal features 116 in the functional circuit portion 170. The test line portion metal features 116T may have substantially the same structure and composition as the metal features 116 in the functional circuit portion 170. The test line portion metal features 116T may be formed concurrently with the metal features 116 and in the same processing steps as the metal features 116.

The second die test line portion 180-2 in the second die 120 may have a configuration associated with the configuration of the functional circuit portion 170 of the second die 120. In at least one embodiment, the second die test line portion 180-2 may include a metal pattern that is substantially the same as a metal pattern in the functional circuit portion 170 of the second die 120.

The test line portion metal features 116T may be electrically coupled to the metal features 116 of the function circuit portion 170. The second die test line portion 180-2 may be electrically coupled to the first die 110 through the functional circuit portion 170 of the second die 120. In particular, the second die test line portion 180-2 may be electrically coupled to the first die 110 through the metal features 116 and the TSV 129 of the functional circuit portion 170 and the bonding layer bonding pad 157 in the bonding layer 150.

The second die test line portion 180-2 may include one or more test line portion seal rings 117T that are substantially the same structure and composition as the second die seal ring 117-2 in the functional circuit portion 170. The test line portion seal rings 117T may have a substantially similar structure as the second die seal ring 117-2. The test line portion seal rings 117T may be formed concurrently with the second die seal ring 117-2 and in the same processing steps as the second die seal ring 117-2.

The second die seal ring 117-2 and/or the test line portion seal rings 117T may also include alignment marks or fiducials that aid in the precise positioning of the second die 120 during assembly and packaging and thereby improve the overall quality and reliability of the semiconductor device 100. The second die seal ring 117-2 and/or the test line portion seal rings 117T may also provide scribe lines for guiding a dicing tool to make precise cuts in separating the second die 120 from other semiconductor devices formed on the first carrier substrate 102.

The second die test line portion 180-2 may include a test line electrical connection design that may allow for tool testing of the semiconductor device 100. In at least one embodiment, the second die test line portion 180-2 may be configured to permit testing of the semiconductor device 100 (e.g., testing of all of the functional dies in the semiconductor device 100) such as by a wafer acceptance testing (WAT) device. In at least one embodiment, second die test line portion 180-2 may be used to monitor an influence of processing on the semiconductor device 100. In at least one embodiment, the second die test line portion 180-2 may be used to monitor a charging damage effect on the semiconductor device 100.

FIG. 1B is a schematic illustration of the semiconductor device 100 in a top-down (z-direction) view according to one or more embodiments. The schematic illustration in FIG. 1B illustrates a relative lateral location (e.g., in the x-y plane) of the first die 110, second die 120, third die 130 and first carrier substrate 102 in the semiconductor device 100. The schematic illustration in FIG. 1B further illustrates a relative lateral location of the first die seal ring 117-1, the second die seal ring 117-2 and the test line portion seal ring 117T in the semiconductor device 100. The first encapsulation layer 118 and second encapsulation layer 128 are omitted from FIG. 1B for ease of understanding. The vertical cross-sectional view in FIG. 1A is across the line A-A′ in the schematic illustration of FIG. 1B.

As illustrated in FIG. 1B, an area of the first die 110 may be less than an area of the third die 130. A length in the x-direction of the die 110 may be less than a length in the x-direction of the first carrier substrate 102. A width in the y-direction of the second die 120 may be less than a width in the y-direction of the first carrier substrate 102.

An area of the second die 120 may be greater than a combined area of the first die 110 and the third die 130. A combined length in the x-direction of the first die 110 and the third die 130 may be less than a length in the x-direction of the second die 120. A greatest width in the y-direction of the first die 110 and third die 130 may be less than a width in the y-direction of the second die 120. In at least one embodiment, each of the first die 110 and third die 130 may be located laterally within the area of the second die 120 (e.g., within the second die edge 120a).

An area of the first carrier substrate 102 may be greater than the area of the second die 120. A length in the x-direction of the second die 120 may be less than a length in the x-direction of the first carrier substrate 102. A width in the y-direction of the second die 120 may be less than a width in the y-direction of the first carrier substrate 102. In at least one embodiment, the second die 120 may be located laterally within the area of the first carrier substrate 102.

As further illustrated in FIG. 1B, the first die 110 may be located within the second die seal ring 117-2. The third die 130 may include a first portion located over the functional circuit portion 170 of the second die 120 and a second portion located over the second die test line portion 180-2 of the second die 120. The second die test line portion 180-2 may include a plurality of test line portion seal rings 117T and a plurality of test line portion metal features 116T. The plurality of test line portion metal features 116T may be located within the test line portion seal rings 117T and/or outside the test line portion seal rings 117T.

FIG. 1C is an exploded perspective view of the semiconductor device 100 according to one or more embodiments. The first bonding film 141, bonding layer 150, passivation layer 138, second bonding film 142 and metal bump 190 are omitted from FIG. 1C for ease of explanation.

The dashed line in the z-direction in FIG. 1C is used to identify a centerpoint of the semiconductor device 100. The centerpoint of each of the first layer 10, second layer 20 and first carrier substrate 102 may be substantially aligned with the centerpoint of the semiconductor device 100. In at least one embodiment the sidewall 118a of the first encapsulation layer 118 may substantially aligned with the sidewall 128a of the second encapsulation layer 128 and with the sidewall 102a of the first carrier substrate 102 around an entire periphery of the semiconductor device 100.

In the first layer 10 of the semiconductor device 100, the first encapsulation layer 118 may surround an entire periphery of the first die 110 and an entire periphery of the third die 130. The first layer 10 may include a substantially uniform upper surface. An upper surface of the first die 110 may be constituted by an upper surface of the die substrate 108 in the first die 110. In at least one embodiment, an upper surface of the first encapsulation layer 118 may be substantially coplanar with an upper surface of the die substrate 108 in the first die 110 and an upper surface of the third die 130.

In the second layer 20 of the semiconductor device 100, the second encapsulation layer 128 may surround an entire periphery of the second die 120. The second layer 20 may include a substantially uniform upper surface. An upper surface of the second die 120 may be constituted by an upper surface of the die substrate 108 in the second die 120. In at least one embodiment, an upper surface of the second encapsulation layer 128 may be substantially coplanar with an upper surface of the die substrate 108 in the second die 120.

Generally, the semiconductor device 100 may be formed by forming the first layer 10 on the first carrier substrate 102, and forming the second layer 20 on the first layer 10. In at least one embodiment, the semiconductor device 100 may be formed in a process in which a plurality of semiconductor devices are formed concurrently on a carrier substrate. In that process, the first layer 10 may be formed by mounting a plurality of the first dies 110 and a plurality of the third dies 130 on the carrier substrate and encapsulating the first dies 110 and third dies 130 in the first encapsulation layer 118. The second layer 20 may then be formed by mounting a plurality of the second dies 120 on the first layer 10 and encapsulating the second dies 120 in the second encapsulation layer 128. A dicing step may then be performed to separate the plurality of semiconductor devices.

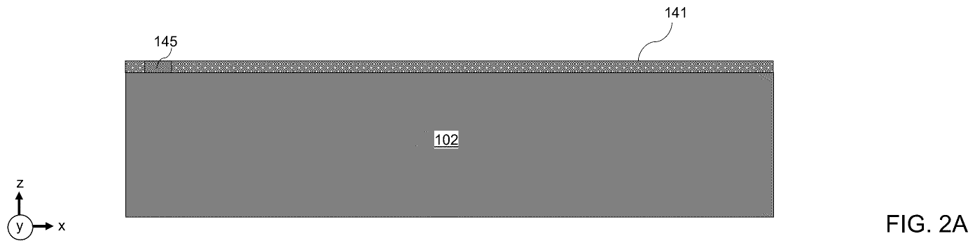

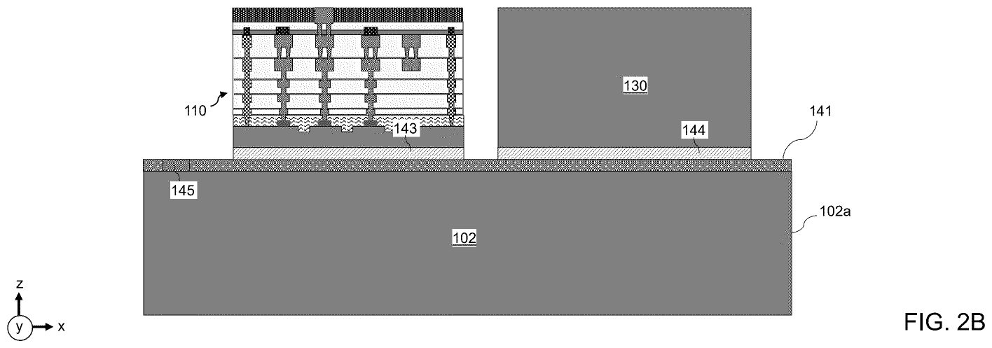

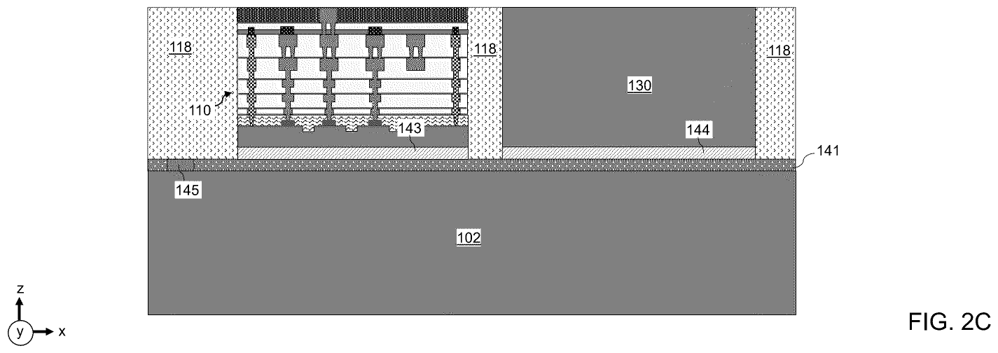

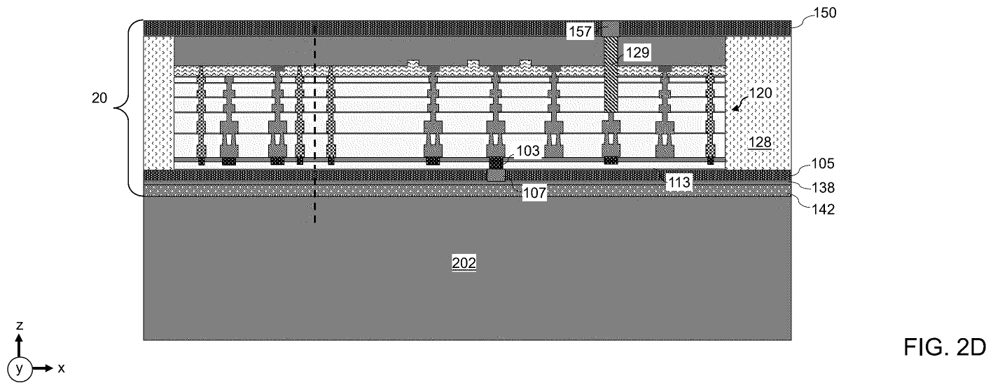

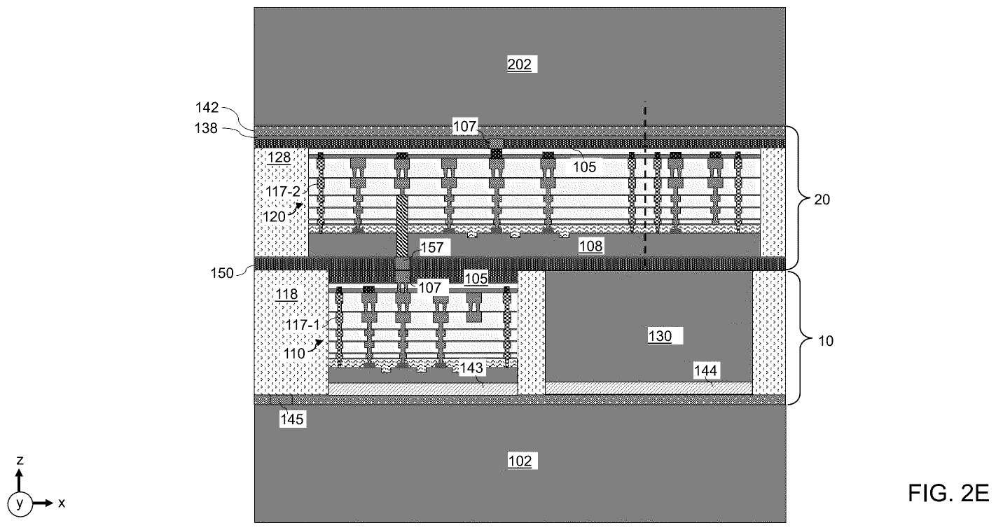

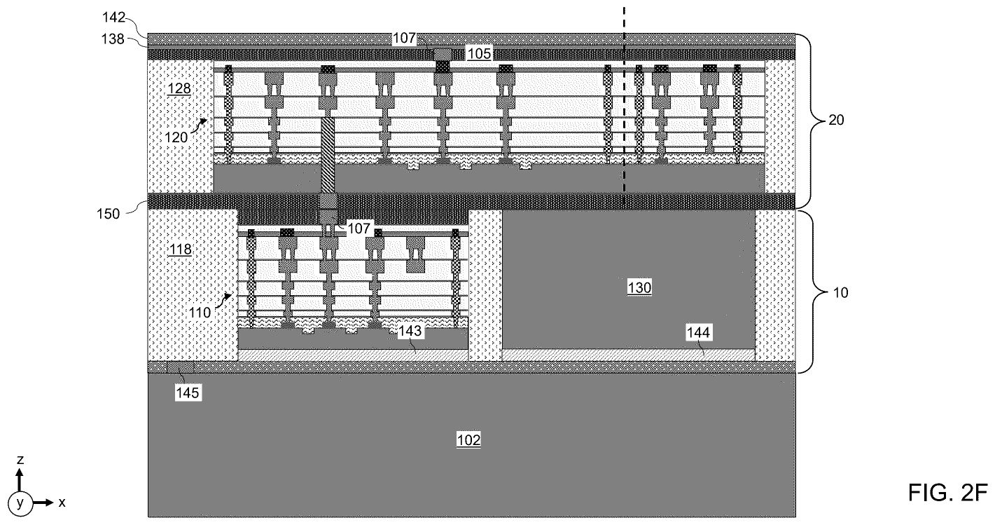

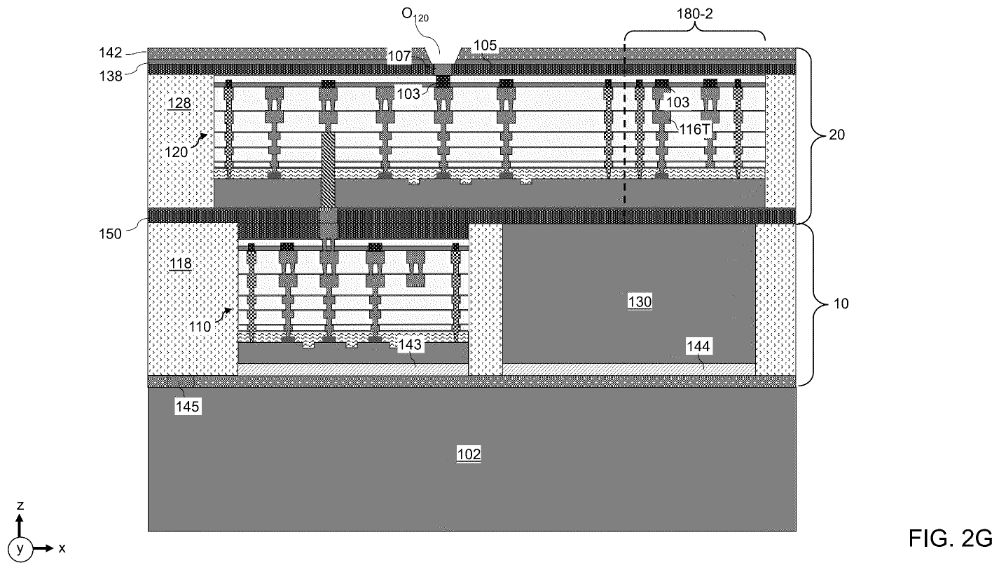

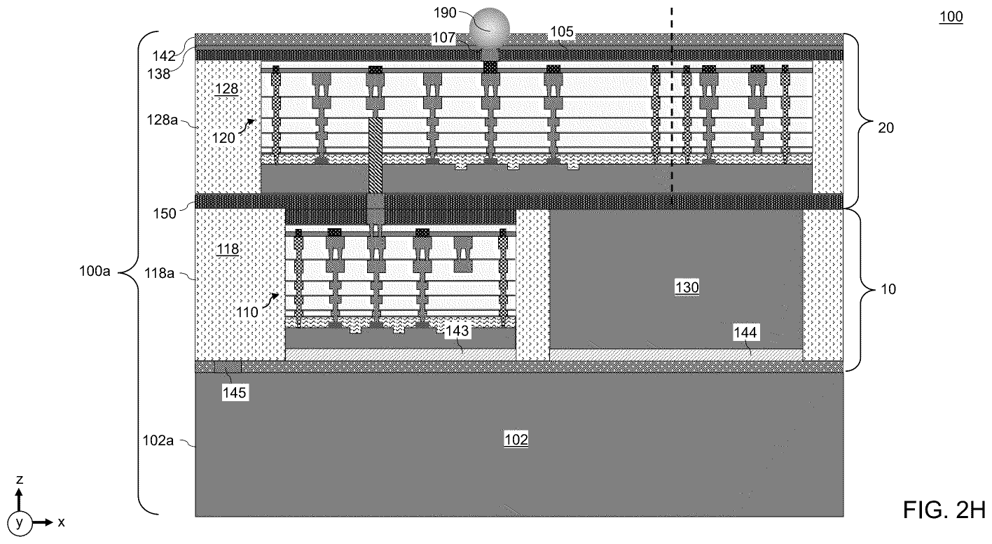

FIGS. 2A-2H illustrate various intermediate structures in a method of forming the semiconductor device 100 according to one or more embodiments. FIG. 2A is an intermediate structure including the first bonding film 141 on the first carrier substrate 102 according to one or more embodiments.

In at least one embodiment, the first carrier substrate 102 may be placed on a flat surface and the first bonding film 141 may be formed on an upper surface of the first carrier substrate 102. The first bonding film 141 may be formed on the upper surface of the first carrier substrate 102. In at least one embodiment, the first bonding film 141 may be formed by a depositing a bonding material by a suitable deposition method such as CVD, PVD, PECVD, LPCVD, ALD, spin-on coating, lamination, etc. The bonding material may then be planarized (e.g., by wet etching, drying etching, etc.) so as to form the first bonding film 141.

The alignment mark 145 may then be formed in the first bonding film 141. An opening for the alignment mark 145 may be formed in the first bonding film 141 by a photolithographic process. The photolithographic process may be similar to the photolithographic process described above for forming the metal features 116 in the first die 110. In the photolithographic process, a photoresist mask (not shown) may be formed on a surface of the first bonding film 141. The photoresist mask may be photolithographically patterned to include an opening. An etching process (e.g., wet etching, dry etching, etc.) may then be used to form an opening in the first bonding film 141 through the opening in the photoresist mask. The opening in the first bonding film 141 may be formed to expose a surface of the first carrier substrate 102. The photoresist mask may be subsequently removed by ashing, dissolving the photoresist mask or by consuming the photoresist mask during the etch process.

A layer of metal material (e.g., copper) may then be deposited (e.g., by CVD, PVD or other suitable process) on the first bonding film 141 and in the opening in the first bonding film 141. Excess metal material may then be removed (e.g., by CMP or other suitable planarizing process) so as to form the alignment mark 145 with a surface substantially coplanar with a surface of the first bonding film 141.

FIG. 2B is an intermediate structure including the first die 110 and third die 130 on the first bonding film 141 according to one or more embodiments. In at least one embodiment, the first die 110 may be placed on the first bonding film 141 by using an electromechanical pick-and-place (PNP) machine. The third die 130 may be placed on the first bonding film 141 separately from the first die 110 (e.g., in a separate step). The third die 130 may be placed on the first bonding film 141 adjacent to the first die 110 by using the PNP machine. The third die 130 may alternatively be placed on the first bonding film 141 first and the first die 110 placed on the first bonding film 141 adjacent the third die. The third die 130 may alternatively be placed on the first bonding film 141 concurrently with the first die 110 in a single step. In at least one embodiment, the first alignment mark 145 may be used to assist in properly aligning (e.g., locating, placing, etc.) the first die 110 and/or the third die 130.

As illustrated in FIG. 2B, the first die 110 and third die 130 may be placed on the first bonding film 141 so as to provide sufficient separation between the first die 110 and third die 130. The separation may allow a sufficient quantity of the first encapsulation layer 118 to be formed in the gap between the first die 110 and third die 130 (see FIG. 1C). The separation may also allow the first encapsulation film 118 to fill the gap (e.g., completely fill the gap) without leaving air pockets in the gap. The first die 110 and third die 130 may also be placed on the first bonding film 141 so that the combined length of the first die 110 and third die 130 in the x-direction is less than the length of the second die 120 in the x-direction (see FIG. 1A).

FIG. 2C is an intermediate structure including the first encapsulation layer 118 on the first bonding film 141 according to one or more embodiments. The first encapsulation layer 118 may be formed on the first bonding film 141 so as to encapsulate (e.g., at least partially encapsulate) the first die 110 and third die 130. The first encapsulation layer 118 (e.g., an encapsulation material) may be deposited on the first bonding film 141. The first encapsulation layer 118 may be deposited by a suitable deposition method such as CVD, PVD, PECVD, LPCVD, ALD, spin-on coating, lamination, etc.

In at least one embodiment, the first encapsulation layer 118 may be formed to have a height in the z-direction greater than a height of the first die 110 and greater than a height of the third die 130. After the first encapsulation layer 118 has been formed, a planarization process (e.g., chemical mechanical polish (CMP)) may then be performed to planarize an upper surface of the first encapsulation layer 118, an upper surface of the first die 110 and an upper surface of the third die 130. The upper surface of the first encapsulation layer 118, upper surface of the first die 110 and upper surface of the third die 130 may be made co-planar by the planarization process. The planarization process may also complete the formation of the first layer 10 (except for the dicing step to separate the semiconductor device 100).

FIG. 2D is an intermediate structure including the second layer 20 on a second carrier substrate 202 according to one or more embodiments. The second carrier substrate 202 may be substantially similar to the first carrier substrate 102. The second layer 20 may be formed on the second carrier substrate 202 in a manner substantially similar to the manner in which the first layer 10 is formed on the first carrier substrate 102 (e.g., see FIGS. 2A-2C).

An adhesive layer (not shown) may be applied to an upper surface of the second carrier substrate 202. The second carrier substrate 202 may include an optically transparent material such as glass or sapphire. The adhesive layer may include, for example, a light-to-heat conversion (LTHC) layer or thermally decomposing adhesive material. Other suitable decomposable adhesive materials are within the contemplated scope of disclosure.

The second bonding film 142 may be formed on the adhesive layer on the upper surface of the second carrier wafer 202. The second bonding film 142 may be formed on the upper surface of the second carrier substrate 202. The second bonding film 142 may be formed in the same manner as the first bonding film 141. In at least one embodiment, the second bonding film 142 may be formed by depositing a bonding material using a suitable deposition method such as CVD, PVD, PECVD, LPCVD, ALD, spin-on coating, lamination, etc. The bonding material may then be planarized (e.g., by wet etching, drying etching, etc.) so as to form the second bonding film 142.

The passivation layer 138 may then be formed on the second bonding film 142. The passivation layer 138 may be formed on the second layer 20. The passivation layer 138 may be formed by depositing (e.g., by CVD, PVD or other suitable deposition technique) one or more layers of passivation material including silicon oxide, silicon nitride, low-k dielectric materials such as carbon-doped oxides, extremely low-k dielectric materials such as porous carbon doped silicon dioxide, a combination thereof or other suitable material. The passivation material may then be planarized (e.g., by wet etching, drying etching, etc.) so as to form the passivation layer 138.

The die bonding film 105 may then be formed on the passivation layer 138. In at least one embodiment, the die bonding film 105 may be formed by depositing a bonding material using a suitable deposition method such as CVD, PVD, PECVD, LPCVD, ALD, spin-on coating, lamination, etc. The bonding material may then be planarized (e.g., by wet etching, drying etching, etc.) so as to form the die bonding film 105.

The second die 120 may then be placed on the die bonding film 105 by using an electromechanical PNP machine. The second die 120 may inverted so that a backside of the second die 120 contacts the die bonding film 105. In particular, the backside etch stop layer 113 may be aligned with the die bonding film 105 so that an exposed contact pad 103 in the second die 120 contacts the die bonding pad 107 in the die bonding film 105.

The second encapsulation layer 128 may then be formed on the second die 120 by a method similar to the method of forming the first encapsulation layer 118 described above. In particular, the second encapsulation layer 128 may be formed on the second die 120 and on the passivation layer 138 around the second die 120 so as to encapsulate (e.g., at least partially encapsulate) the second die 120. The second encapsulation layer 128 (e.g., an encapsulation material) may be deposited on the second die 120 and the passivation layer 138. The second encapsulation layer 128 may be deposited by a suitable deposition method such as CVD, PVD, PECVD, LPCVD, ALD, spin-on coating, lamination, etc.

In at least one embodiment, the second encapsulation layer 128 may be formed to have a height in the z-direction greater than a height of the second die 120. After the second encapsulation layer 128 has been sufficiently formed, a planarization process (e.g., CMP) may then be performed to planarize a surface of the second encapsulation layer 128 and a surface of the second die 120. The surface of the second encapsulation layer 128 and surface of the second die 120 may be made co-planar by the planarization process.

The bonding layer 150 may then be formed on the surface of the second encapsulation layer 128 and surface of the second die 120. The bonding layer 150 may be formed in a manner substantially similar to the manner of forming the first bonding film 141 and the manner of forming the second bonding film 142. In at least one embodiment, the bonding layer 150 may be formed on the surface of the second encapsulation layer 128 and surface of the second die 120. In at least one embodiment, the bonding layer 150 may be formed by a suitable deposition method such as CVD, PVD, PECVD, LPCVD, ALD, spin-on coating, lamination, etc. In at least one embodiment, the bonding material may be deposited by CVD and a source of the bonding material may include a gas or liquid (e.g., tetraethyl orthosilicate (TEOS)).

The bonding layer bonding pad 157 may then be formed in the bonding layer 150. An opening may be formed in the bonding layer 150 by a photolithographic process. The photolithographic process may be similar to the photolithographic process described above for forming the metal features 116 in the first die 110. In the photolithographic process, a photoresist mask (not shown) may be formed on a surface of the bonding layer 150. The photoresist mask may be photolithographically patterned to include an opening over the TSV 129. An etching process (e.g., wet etching, dry etching, etc.) may then be used to form an opening in the bonding layer 150 through the opening in the photoresist mask. The opening in the bonding layer 150 may be formed to expose a surface of the TSV 129. The photoresist mask may be subsequently removed by ashing, dissolving the photoresist mask or by consuming the photoresist mask during the etch process.

A metal layer may then be formed on the bonding layer 150, in the opening of the bonding layer 150 and onto the surface of the TSV 129. The metal layer may be formed by a suitable deposition process such as CVD, PVD, PECVD, LPCVD, ALD, spin-on coating, lamination, etc. The metal layer may then be planarized (e.g., by CMP) so that a surface of the bonding layer bonding pad 157 is substantially co-planar with the surface of the bonding layer 150. The forming of the bonding layer bonding pad 157 complete the formation of the second layer 20.

FIG. 2E is an intermediate structure including the second layer 20 on the first layer 10 according to one or more embodiments. In at least one embodiment, the second layer 20 may be bonded to the first layer 10 in a wafer-to-wafer bonding process.

The second layer 20 may be placed on first layer 10, for example, by an electromechanical PNP machine. In particular, the intermediate structure in FIG. 2D may be inverted and positioned over the first layer 10 so that the second layer 20 is between the first layer 10 and the second carrier substrate 202. The second layer 20 may then be lowered onto the first layer 10 so that the bonding layer 150 in the second layer 20 contacts the first encapsulation layer 118, the die bonding film 105 which is formed at the backside of the first die 110, and the third die 130. The second layer 20 may also be positioned on the first layer 10 so that the bonding layer bonding pad 157 in the bonding layer 150 contacts the die bonding pad 107 in the first die 110.

The second layer 20 may also be positioned on the first layer 10 so that the second die 120 is located over the first die 110 and third die 130. In at least one embodiment, the second die 120 may be positioned so that the second die 120 is located over an entirety of the first die 110 and an entirety of the third die 130 (see FIG. 1B). The second layer 20 may also be positioned so that the first seal ring 117-1 in the first die 110 is located within the second seal ring 117-2 in the second die 120 (see FIG. 1B).

A bonding process may then be performed to bond the second layer 20 to the first layer 10 through the bonding layer 150. The bonding process may form, for example, a hybrid bond in which bonding layer bonding pad 157 in the bonding layer 150 is bonded to the die bonding pad 107 in the first die 110 and the bonding layer 150 is bonded to the die bonding film 105 of the first die 110. The bonding layer 150 may also be bonded to the first encapsulation layer 118 of the first layer 10. The bonding process may be performed at room temperature (room-temperature bonding) or at elevated temperatures (thermal bonding) depending on the specific bonding technique used.

FIG. 2F is an intermediate structure after removal of the second carrier substrate 202 according to one or more embodiments. The second carrier substrate 202 may be detached from the second bonding film 142, for example, by deactivating the adhesive layer (not shown) adhering the second carrier substrate 202 to the second bonding film 142. The adhesive layer may be deactivated, for example, by a thermal anneal at an elevated temperature or by exposing the adhesive layer to ultraviolet light. metal

FIG. 2G is an intermediate structure including a multilayer opening 0120 in the passivation layer 138 and the second bonding film 142 according to one or more embodiments. The multilayer opening 0120 may be formed in the passivation layer 138 and the second bonding film 142 by a photolithographic process. The photolithographic process may be similar to the photolithographic process described above for forming the metal features 116 in the first die 110. In the photolithographic process, a photoresist mask (not shown) may be formed on an upper surface of the second bonding film 142. The photoresist mask may be photolithographically patterned to include an opening over the die bonding pad 107. An etching process (e.g., wet etching, dry etching, etc.) may then be used to form the multilayer opening 0120 in the second bonding film 142 and the passivation layer 138 through the opening in the photoresist mask. The multilayer opening 0120 in the second bonding film 142 and the passivation layer 138 may be formed to expose an upper surface of the die bonding pad 107. The photoresist mask may be subsequently removed by ashing, dissolving the photoresist mask or by consuming the photoresist mask during the etch process.

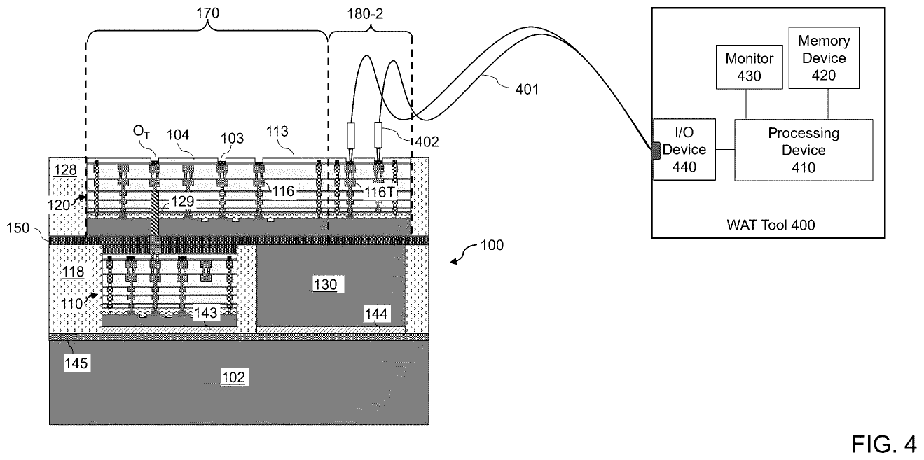

It should be noted that at this point (e.g., before a bump loop process), testing such as wafer acceptance testing (WAT) may be performed on the semiconductor device 100. In that case, test openings similar to the multilayer openings 0120 may be formed in the intermediate structure of FIG. 2G. The test openings may be formed in the second bonding film 142, passivation layer 138 an die bonding film 105 to expose a surface of the contact pads 103 electrically coupled to (e.g., contacting) the test line portion metal features 116T in the second die test line portion 180-2 of the second die 120. One or more testing probes of a WAT tool may then be inserted into the test openings to contact the contact pads 103 and perform the testing of the semiconductor device. It should be noted that the timing of WAT testing is not necessarily limited but may be performed at other stages of the manufacturing process. Further details of the testing by the WAT tool are provided below (e.g., see FIG. 4).

FIG. 2H is an intermediate structure including the metal bump 190 on the die bonding pad 107 in the multilayer opening 0120 according to one or more embodiments. The metal bump 190 may include, for example, a C4 bump including a solder ball formed on the die bonding pad 107. The metal bump 190 may be formed, for example, by one or more processes including ball mounting, electroplating, solder printing, solder immersion and solder injection. The metal bump 190 may contact the die bonding pad 107 and a sidewall of the multilayer opening 0120 in the passivation layer 138 and the second bonding film 142. In at least one embodiment, one or more underbump metallization (UBM) layers (not shown) may be formed on the die bonding pad 107. The metal bump 190 may then be formed so as to contact the die bonding pad 107 through the UBM layers.

After forming the metal bump 190, a dicing process may be performed to separate the semiconductor device 100 from the other semiconductor devices formed on the first carrier substrate 102 (e.g., carrier wafer). The dicing process may result in the formation of the sidewall 100a of the semiconductor device 100 including the sidewall 128a of the second encapsulation layer 128, the sidewall 118a of the first encapsulation layer 118a and the sidewall 102a of the first carrier substrate 102.

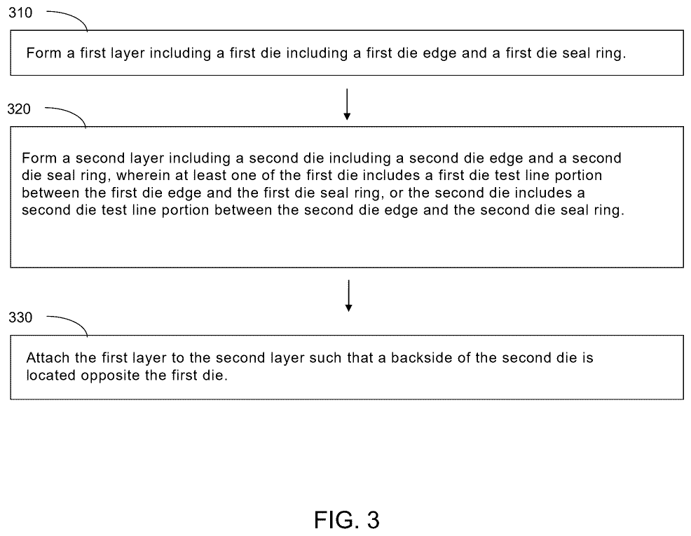

FIG. 3 is a flow chart illustrating a method of forming a semiconductor device according to one or more embodiments. With reference to FIGS. 1A, 21, 5A, 7, and 8, step 310 includes forming a first layer 10 including a first die 110 including a first die edge 110a and a first die seal ring 117-1. Step 320 includes forming a second layer 20 including a second die 120 including a second die edge 120a and a second die seal ring 117-2, wherein at least one of the first die 110 includes a first die test line portion 180-1 between the first die edge 110a and the first die seal ring 117-1, or the second die 120 includes a second die test line portion 180-2 between the second die edge 120a and the second die seal ring 117-2. Step 330 includes attaching the first layer 10 to the second layer 20 such that a backside 120b of the second die 120 is located opposite the first die 110.

FIG. 4 is a schematic illustration of a method of testing the semiconductor device 100 according to one or more embodiments. In at least one embodiment, the testing of the semiconductor device 100 may utilize the second die test line portion 180-2 in the second die 120. In at least one embodiment, the testing of the semiconductor device 100 may include wafer acceptance testing (WAT). In at least one embodiment, a wafer acceptance testing tool 400 may be used to perform the testing of the semiconductor device 100.

Wafer acceptance testing may play an important role in semiconductor fabrication by helping to ensure the quality and reliability of semiconductor wafers before they proceed to subsequent manufacturing processes. It may be performed, for example, near the end of the semiconductor device fabrication process (e.g., wafer fabrication process) or after completion of the semiconductor device fabrication process.

An objective of wafer acceptance testing may include identifying any defects, faults, or deviations in the electrical and physical characteristics of the semiconductor device 100. The testing may involve subjecting the semiconductor device 100 to a series of tests to assess its functionality, performance, and overall quality. The testing may be performed using the wafer acceptance testing tool 400 and test structures that are designed to measure various parameters and behaviors of one or more integrated circuits (ICs) in the first die 110 and second die 120 of the semiconductor device 100.

The WAT tool 400 may perform, for example, electrical testing of the semiconductor device 100. This may involve probing the individual ICs in the semiconductor device 100 to measure the ICs' electrical characteristics. Various tests may be performed by the WAT tool 400, such as measuring current-voltage (IV) curves, checking for shorts and opens, verifying power supply voltages, and analyzing the functionality of different circuit elements.

The WAT tool 400 may also perform parametric testing to measure critical electrical parameters of the ICs, such as voltage levels, currents, timings, and capacitances. These tests may help ensure that the ICs meet the specified performance requirements.

The WAT tool 400 may also perform functional testing to evaluate the overall functionality of the ICs by subjecting them to specific input stimuli and verifying the expected output responses. This may help ensure that the ICs perform their intended functions correctly.

The WAT tool 400 may also perform reliability tests to assess the long-term durability and stability of the ICs under various operating conditions. These tests include temperature cycling, burn-in testing, electrostatic discharge (ESD) testing, and other stress tests to simulate real-world usage scenarios and identify potential failure mechanisms.

The WAT tool 400 may also perform defect detection to inspect the semiconductor device 100 for physical defects using techniques such as optical microscopy, scanning electron microscopy (SEM), and other non-destructive testing methods. Defects such as contamination, particles, scratches, or pattern irregularities may be identified and categorized by the WAT tool 400.

The WAT tool 400 may also statistically analyze the data obtained by testing the semiconductor device 100 to determine the overall quality of a batch of the semiconductor devices 100. Data from the batch of semiconductor devices 100 may be collected and analyzed to assess process variations, yield rates, and identify any systematic issues that need to be addressed. The batch of semiconductor devices 100 may be accepted or rejected based on the results of testing by the WAT tool 400.

Referring again to FIG. 4, in at least one embodiment, the WAT tool 400 may be implemented by a computer, server, etc. The WAT tool 400 may include a processing device 410 such as a central processing unit (CPU), microprocessor, etc. The WAT tool 400 may also include a memory device 420 (e.g., random access memory (RAM), read-only memory (ROM), etc.). The memory device 420 may store data and programs including instructions form performing various operations in the WAT tool 400. The memory device 420 may also store data generated by the testing performed by the WAT tool 400. The processing device 410 may access the data and programs in the memory device 420, and execute the instructions in order to perform various methods including a method of testing (e.g., wafer acceptance testing) the semiconductor device. The processing device 410 may also store test data generated by the testing performed by the WAT tool 400 in the memory device 420. The processing device 410 may also perform analysis on the test data of testing performed by the WAT tool 400, generate test analysis data based on the analysis and store the test analysis data in the memory device 420. The WAT tool 400 may also include a monitor 430 (e.g., display device) and the processing device 410 may generate a display signal for generating a display on the monitor 430 including the test data, test analysis data, etc.

The WAT tool 400 may also include an input/output (I/O) device 440 (e.g., signal transmitter/receiver) for transmitting a test signal generated by the processing device 410 or according to an instruction generated by the processing device 410. The I/O device 440 may also receive a signal from the semiconductor device 100 in response to the test signal.

The WAT tool 400 may include one or more testing probes 402 connected to the I/O device 400 by a signal transmission cable 401. Other forms of signal transmission, such as wireless forms may be used. A method of testing the semiconductor device 100 may include forming one or more test openings OT in the functional circuit portion 170 and second die test line portion 180-2 of the second die 120. The test openings OT may be formed, for example, by performing a photolithographic process (similar to the photolithograpic process described above for forming the metal features 116 in the first die 110). The test openings OT may include multilayer openings formed in the backside etch stop layer 113 and gap fill dielectric layer 104. The test openings OT may be formed to expose a surface of the contact pads 103 electrically coupled to (e.g., contacting) the metal features 116 in the functional circuit portion 170 of the second die 120. The test openings OT may also be formed to expose a surface of the contact pads 103 electrically coupled to (e.g., contacting) the test line portion metal features 116T in the second die test line portion 180-2 of the second die 120.

The probes 402 may then be inserted into the test openings OT so as to contact one or more of the exposed contact pads 103 in the second die test line portion 180-2. The probes 402 may electrically couple the WAT tool 400 to the contact pads 103 through the cables 401. The WAT tool 400 may then transmit a test signal through a cable 401 and probe 402 to the exposed contact pad 103. The test signal may be transmitted from the contact pad 103 through an integrated circuit included in the first die 110 and second die 120. Another probe 402 contacting another exposed contact pad 103 may detect a response to the test signal and transmit the response through another cable 401 to the WAT tool 400.

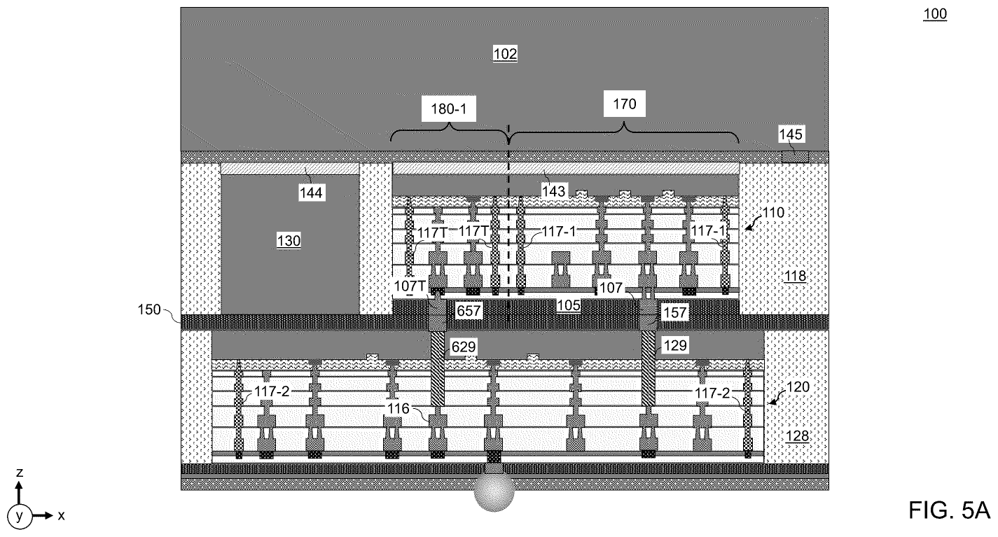

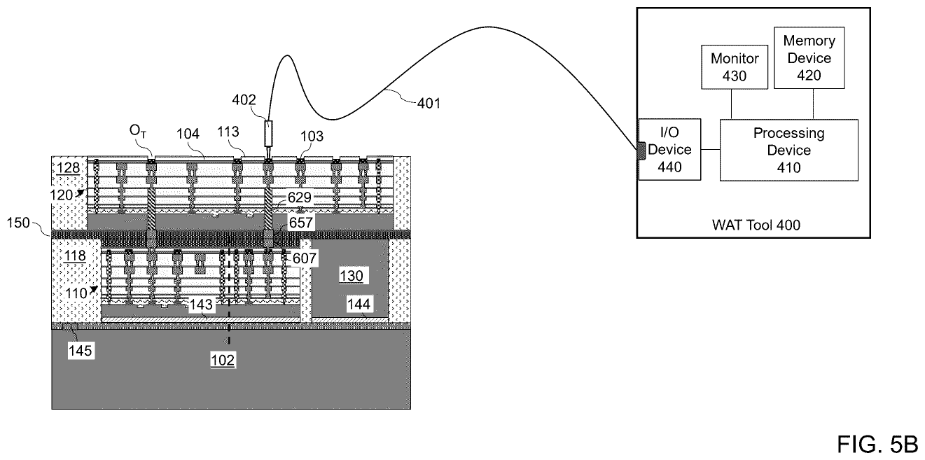

FIG. 5A is a vertical cross-sectional view of the semiconductor device 100 having a first alternative design according to one or more embodiments. As illustrated in FIG. 5A, the first alternative design of the semiconductor device 100 may be substantially similar to the original design in FIG. 1A. However, in the first alternative design, the semiconductor device 100 includes a first die test line portion 180-1 in the first die 110. The first die test line portion 180-1 may be adjacent the functional circuit portion 170 in the first die 110. The first die test line portion 180-1 may be substantially similar to the second die test line portion 180-2 in the original design in FIG. 1A.

To accommodate the first die test line portion 180-1, the length of the first die 110 in the x-direction may be greater than the length of the first die 110 in the x-direction in the original design in FIG. 1A. The length of the third die 130 in the x-direction may also be greater than the length of the third die 130 in the x-direction in the original design in FIG. 1A.

The first die test line portion 180-1 may be accessed during wafer acceptance testing through the second die 120. To allow access to the first die test line portion 180-1, the first die test line portion 180-1 may include a test line portion bonding pad 107T in the die bonding film 105 of the first die 110. The test line portion bonding pad 107T may be substantially similar to the bonding pad 107 in the die bonding film 105 of the first die 110. The semiconductor device 100 may also include a bonding layer bonding pad 657 in the bonding layer 150. The bonding layer bonding pad 657 may contact the test line portion bonding pad 107T. The bonding layer bonding pad 657 may be substantially similar to the bonding layer bonding pad 157 in the bonding layer 150. The second die 120 may also include a TSV 629 electrically coupled to the bonding layer bonding pad 657 in the bonding layer 150 and the metal features 116 in the second die 120. The TSV 629 may be substantially similar to the TSV 129 in the second die 120. The TSV 629 may be substantially similar to the TSV 129 in the second die 120. The first die test line portion 180-1 may thereby be electrically coupled to the second die (e.g., a functional circuit area of the second die 120).

The first die test line portion 180-1 in the first die 110 may, therefore, be used as a test line. In particular, the first die test line portion 180-1 may be used to monitor the influence of the process on the semiconductor device 100 having the first design and the integrated circuit in the semiconductor device.

In the first alternative design, the semiconductor device 100 may include a connecting structure including the test line portion bonding pad 607, the bonding layer bonding pad 657 in the bonding layer 150 and the TSV 629 in the second die 120. However, it should be noted that the semiconductor device 100 may alternatively include a plurality of the connecting structures between the first die test line portion 180-1 and the second die 120. That is, the semiconductor device 100 may include a plurality of test line portion bonding pads 607, bonding pads 657 and TSVs 629.

FIG. 5B is a schematic illustration of a method of testing the semiconductor device 100 having the first alternative design according to one or more embodiments. The method of testing the semiconductor device 100 having the first alternative design may be substantially similar to the method of testing the semiconductor device 100 having the original design in FIG. 1A (see FIG. 4). In at least one embodiment, the testing of the semiconductor device 100 may utilize the first die test line portion 180-1 in the first die 110. In at least one embodiment, the wafer acceptance testing tool 400 may be used to perform the testing of the semiconductor device 100.

As illustrated in FIG. 5B, the probe 402 may be inserted into the test opening OT so as to contact an exposed contact pad 103 electrically coupled to the TSV 629. The probe 402 may electrically couple the WAT tool 400 to the contact pad 103 through the cable 401. The WAT tool 400 may then transmit a test signal through a cable 401 and probe 402 to the exposed contact pad 103. The test signal may be transmitted from the contact pad 103 through an integrated circuit included in the first die 110 and second die 120. The probe 402 may detect a response to the test signal and transmit the response through cable 401 to the WAT tool 400.

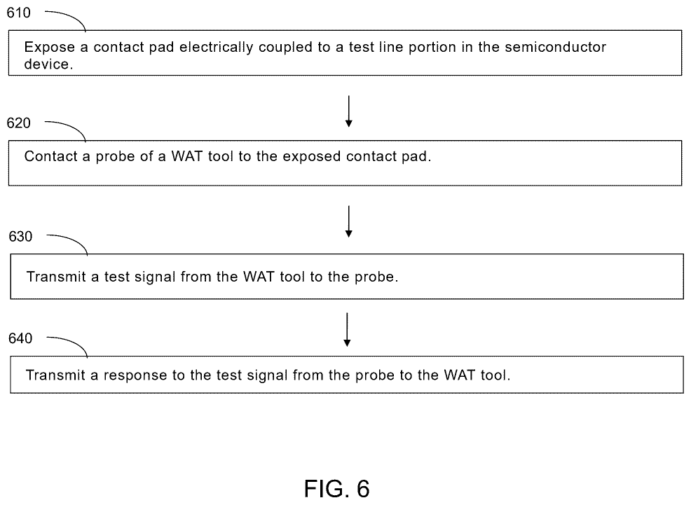

FIG. 6 is a flow chart illustrating a method of testing the semiconductor device 100 according to one or more embodiments. Step 610 includes exposing a contact pad electrically coupled to a test line portion in a die in the semiconductor device. Step 620 includes contacting a probe of a WAT tool to the exposed contact pad. Step 630 includes transmitting a test signal from the WAT tool to the probe. Step 640 includes transmitting a response to the test signal from the probe to the WAT tool.

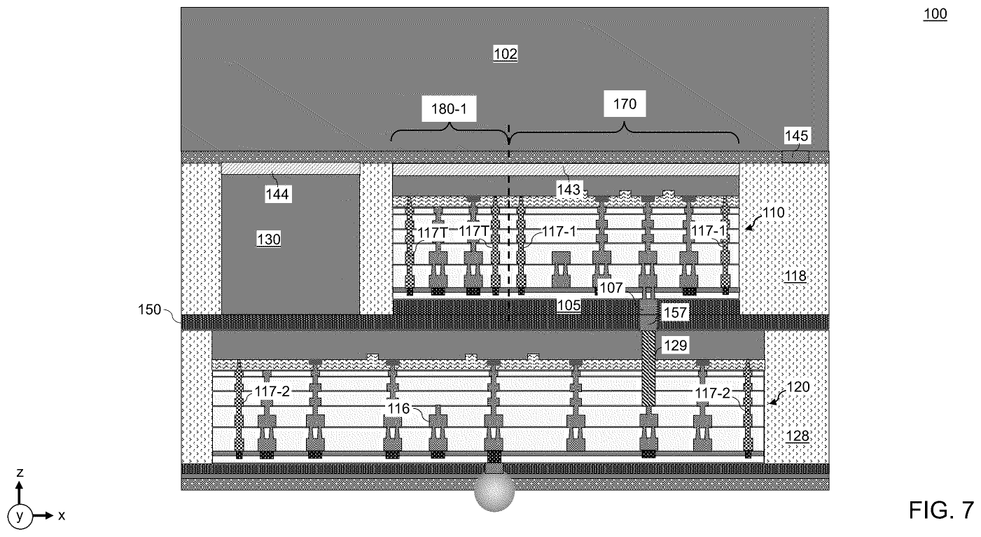

FIG. 7 is a vertical cross-sectional view of the semiconductor device 100 having a second alternative design according to one or more embodiments. As illustrated in FIG. 7, the second alternative design of the semiconductor device 100 may be substantially similar to the first alternative design in FIG. 5A. In particular, the first die 110 may include the first die test line portion 180-1.

However, in the second alternative design, the semiconductor device 100 may not include the connecting structure between the first die test line portion 180-1 and the second die 120. That is, the semiconductor device 100 may not include the test line portion bonding pad 607, bonding layer bonding pad 657 and TSV 629 that may be included in the first alternative design in FIG. 5A.

That is, the first die test line portion 180-1 may not be electrically coupled to the second die 120. In this case, the first die test line portion 180-1 may not be used for testing, but may be used, for example, as a heat dissipation structure. The first die test line portion 180-1 may also be used to reduce the area of the third die 130. In at least one embodiment, the first die test line portion 180-1 may completely eliminate the need for the third die 130. This may help to reduce cost and balance stress (e.g., stress caused by mismatched coefficient of thermal expansions (CTEs)) in the level of the first die (e.g., same level, same structure).

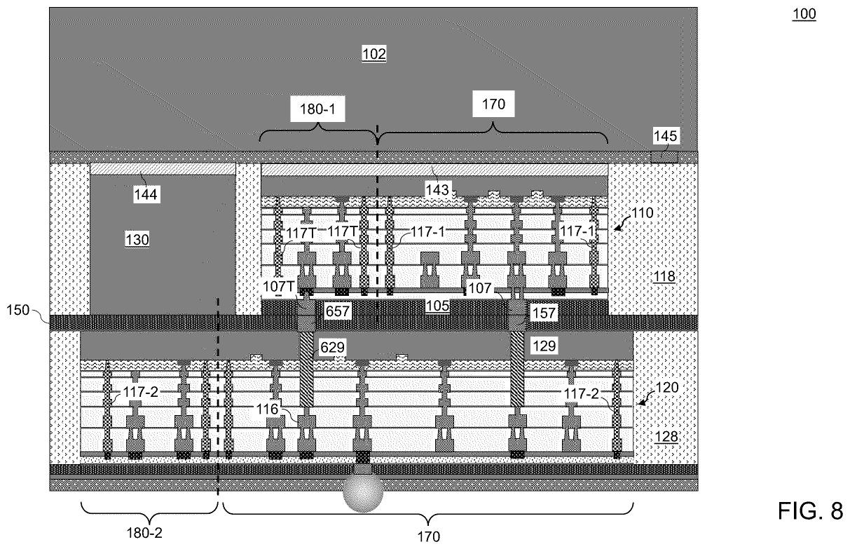

FIG. 8 is a vertical cross-sectional view of the semiconductor device 100 having a third alternative design according to one or more embodiments. As illustrated in FIG. 8, the third alternative design of the semiconductor device 100 may include both the first die test line portion 180-1 in the first die 110 and the second die test line portion 180-2 in the second die 120. Further, the semiconductor device 100 may include the connecting structure between the first die test line portion 180-1 and the second die 120 as in the first alternative design in FIG. 5A. That is, the semiconductor device 100 may include the test line portion bonding pad 607, bonding layer bonding pad 657 and TSV 629. Thus, the first die test line portion 180-1 may be electrically coupled to the second die 120 through the connecting structure.

The third alternative design in FIG. 8 may allow for separate monitoring of the first die 110 and the second die 120. In particular, this design may allow the first die 110 and the second die 120 to be easily analyzed by separate testing by the WAT tool 400 (see FIGS. 4 and 5B). Separate monitoring may be especially advantageous where the first die 110 and the second die 120 are formed in different processes. Separate monitoring may improve the electrical die sorting (EDS) process and may affect the affordability of the semiconductor device 100.

Referring to FIGS. 1A-8, a semiconductor device 100 may include a first die 110 including a first die edge 110a and a first die seal ring 117-1, a second die 120 bonded to the first die 110 and including a second die edge 120a and a second die seal ring 117-2, and a test line portion including at least one of a first die test line portion 180-1 in the first die 110 between the first die edge 110a and the first die seal ring 117-1, or a second die test line portion 180-2 in the second die 120 between the second die edge 120a and the second die seal ring 117-2. The test line portion may include the second die test line portion 180-2, and the second die test line portion 180-2 may include a test line portion metal feature 116T configured to be electrically coupled to a testing tool. The second die test line portion 180-2 may further include a test line portion seal ring 117T around the test line portion metal feature 116T. The second die test line portion 180-2 may be between the second die edge 120a and the second die seal ring 117-2 in a first direction, and a distance between the second die edge 120a and the second die seal ring 117-2 in the first direction may be greater than a distance between the second die edge 120a and the second die seal ring 117-2 in a second direction perpendicular to the first direction. The first die seal ring 117-1 may have a first die seal ring length in the first direction and a first die seal ring width less than the first die seal ring length in the second direction. The second die seal ring 117-2 may have a second die seal ring length in the first direction and a second die seal ring width less than the second die seal ring length in the second direction, and the second die seal ring length may be greater than the first die seal ring length. The second die 120 may further include a die substrate 108, and a via 129 in the die substrate 108 and configured to electrically coupled the second die 120 to the first die 110. The semiconductor device 100 may further include a bonding layer 150 between the first die 110 and the second die 120, and a bonding layer bonding pad 157 in the bonding layer 150 and bonded to the via 129. The first die 110 may include a die bonding film 105, and a die bonding pad 107 in the die bonding film 105, wherein the die bonding pad 107 may be bonded to the bonding layer bonding pad 157. The semiconductor device 100 may further include a dummy die 130 adjacent the first die 110 and bonded to the second die 120 by the bonding layer 150, and a first encapsulation layer 118 encapsulating the dummy die 130 and the first die 110. The semiconductor device 100 may further include a second encapsulation layer 128 encapsulating the second die 120, wherein the second encapsulation layer 128 may be bonded to the first encapsulation layer 118 by the bonding layer 150. The test line portion may include the first die test line portion 180-1, and the first die test line portion 180-1 may include a test line portion metal feature 116T configured to be electrically coupled to a testing tool through the second die 120. The second die 120 may further include a die substrate 108, and a via 129 in the die substrate 108 and configured to electrically couple the second die 120 to the first die test line portion 180-1. The first die test line portion 180-1 may be electrically isolated from the second die 120. The test line portion may include the first die test line portion 180-1 and the second die test line portion 180-2.

Referring again to FIGS. 1A-8, a method of making a semiconductor device 100 may include forming a first layer 10 including a first die 110 including a first die edge 110a and a first die seal ring 117-1, forming a second layer 20 including a second die 120 including a second die edge 120a and a second die seal ring 117-2, wherein at least one of the first die 110 includes a first die test line portion 180-1 between the first die edge 110a and the first die seal ring 117-1, or the second die 120 includes a second die test line portion 180-2 between the second die edge 120a and the second die seal ring 117-2, attaching the first layer 10 to the second layer 20 such that a backside 120b of the second die 120 is located opposite the first die 110. The attaching of the first layer 10 to the second layer 20 may include attaching the first layer 10 to the second layer 20 such that the first die 110 is electrically coupled to a through silicon via (TSV) 129 in the second die 120. The second die 120 may include the second die test line portion 180-2, the second die test line portion 180-2 may include a test line portion metal feature 116T and the forming of the second layer 20 may include forming the second layer 20 such that the test line portion metal feature 116T is accessible through an opening in a passivation layer 138 of the second die 120. The first die 110 may include the first die test line portion 180-1, and the attaching of the first layer 10 to the second layer 20 may include attaching the first layer 10 to the second layer 20 such that the first die test line portion 180-1 is electrically coupled to a through silicon via (TSV) 629 in the second die 120.

Referring again to FIGS. 1A-8, a testing method may include providing a semiconductor device 100 including a first die 110 including a first die edge 110a and a first die seal ring 117-1, a second die 120 bonded to the first die 110 and including a second die edge 120a and a second die seal ring 117-2, and a test line portion including at least one of a first die test line portion 180-1 in the first die 110 between the first die edge 110a and the first die seal ring 117-1, or a second die test line portion 180-2 in the second die 120 between the second die edge 120a and the second die seal ring 117-2, etching the second die 120 to expose a contact pad 103 electrically coupled to a metal feature 116 in the second die 120, and attaching a test probe 402 of a testing tool 400 to the exposed contact pad 103 to electrically couple the testing tool 400 to the test line portion.

The various embodiments disclosed herein provide a semiconductor device 100 that may include easier access to enable testing of various functions or portions of the semiconductor dies 110 and/or 130. By providing a test line portion (180-1/180-2) on either of the first die 110 or second die 120, the semiconductor device 100 design may be more flexible and may increase the ability to monitor the semiconductor device 100 during production. The test line portion (180-1/180-2) may allow a WAT tool 400 to test various functions or portions of the semiconductor dies 110, 120 as well as determine whether physical stresses or thermal expansion during the manufacturing process degrades or damages the semiconductor device 100. This may allow the WAT tool 400 to monitor the influence of the manufacturing process on the semiconductor device 100. Various embodiments are disclosed to form the semiconductor device 100 with stacked semiconductor dies 110, 120, wherein at least one of the stacked dies 110, 120 includes a test line portion (180-1/180-2). In addition, various testing methods are disclosed that may utilize the test line portion (180-1/180-2) to test various functions and/or structures of the semiconductor device 100.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a first die including a first die edge and a first die seal ring;
a second die bonded to the first die and including a second die edge and a second die seal ring; and
a test line portion comprising at least one of:
a first die test line portion in the first die between the first die edge and the first die seal ring; or
a second die test line portion in the second die between the second die edge and the second die seal ring.

2. The semiconductor device of claim 1, wherein the test line portion includes the second die test line portion, and the second die test line portion comprises a test line portion metal feature configured to be electrically coupled to a testing tool.

3. The semiconductor device of claim 2, wherein the second die test line portion further comprises a test line portion seal ring around the test line portion metal feature.

4. The semiconductor device of claim 2, wherein the second die test line portion is between the second die edge and the second die seal ring in a first direction, and a distance between the second die edge and the second die seal ring in the first direction is greater than a distance between the second die edge and the second die seal ring in a second direction perpendicular to the first direction.

5. The semiconductor device of claim 4, wherein the first die seal ring has a first die seal ring length in the first direction and a first die seal ring width less than the first die seal ring length in the second direction.

6. The semiconductor device of claim 5, wherein the second die seal ring has a second die seal ring length in the first direction and a second die seal ring width less than the second die seal ring length in the second direction, and the second die seal ring length is greater than the first die seal ring length.

7. The semiconductor device of claim 2, wherein the second die further comprises:
a die substrate; and
a via in the die substrate and configured to electrically couple the second die to the first die.

8. The semiconductor device of claim 7, further comprising:
a bonding layer between the first die and the second die; and
a bonding layer bonding pad in the bonding layer and bonded to the via.

9. The semiconductor device of claim 8, wherein the first die comprises:
a die bonding film; and
a die bonding pad in the die bonding film, wherein the die bonding pad is bonded to the bonding layer bonding pad.

10. The semiconductor device of claim 8, further comprising:
a dummy die adjacent the first die and bonded to the second die by the bonding layer; and
a first encapsulation layer encapsulating the dummy die and the first die.

11. The semiconductor device of claim 10, further comprising:
a second encapsulation layer encapsulating the second die, wherein the second encapsulation layer is bonded to the first encapsulation layer by the bonding layer.

12. The semiconductor device of claim 1, wherein the test line portion includes the first die test line portion, and the first die test line portion comprises a test line portion metal feature configured to be electrically coupled to a testing tool through the second die.

13. The semiconductor device of claim 12, wherein the second die further comprises:
a die substrate; and
a via in the die substrate and configured to electrically couple the second die to the first die test line portion.

14. The semiconductor device of claim 12, wherein the first die test line portion is electrically isolated from the second die.

15. The semiconductor device of claim 1, wherein the test line portion includes the first die test line portion and the second die test line portion.

16. A method of making a semiconductor device, the method comprising:
forming a first layer comprising a first die including a first die edge and a first die seal ring;
forming a second layer comprising a second die including a second die edge and a second die seal ring, wherein at least one of:
the first die comprises a first die test line portion between the first die edge and the first die seal ring; or
the second die comprises a second die test line portion between the second die edge and the second die seal ring; and
attaching the first layer to the second layer such that a backside of the second die is located opposite the first die.

17. The method of claim 16, wherein the attaching of the first layer to the second layer comprises attaching the first layer to the second layer such that the first die is electrically coupled to a through silicon via (TSV) in the second die.

18. The method of claim 16, wherein the second die includes the second die test line portion, the second die test line portion comprises a test line portion metal feature and the forming of the second layer comprises forming the second layer such that the test line portion metal feature is accessible through an opening in a passivation layer of the second die.

19. The method of claim 16, wherein the first die includes the first die test line portion, and the attaching of the first layer to the second layer comprises attaching the first layer to the second layer such that the first die test line portion is electrically coupled to a through silicon via (TSV) in the second die.

20. A testing method, comprising:
providing a semiconductor device comprising:
a first die including a first die edge and a first die seal ring;
a second die bonded to the first die and including a second die edge and a second die seal ring; and
a test line portion comprising at least one of:
a first die test line portion in the first die between the first die edge and the first die seal ring; or
a second die test line portion in the second die between the second die edge and the second die seal ring;
etching the second die to expose a contact pad electrically coupled to a metal feature in the second die; and
attaching a test probe of a testing tool to the exposed contact pad to electrically couple the testing tool to the test line portion.
